(19) United States
(12) Patent Application Publication
(10) Pub. No.: US 2026/0239826 A1
(43) Pub. Date: Aug. 13, 2026

(54) DISPLAY DEVICE AND ELECTRONIC DEVICE INCLUDING THE DISPLAY DEVICE

(71) Applicant: Samsung Display Co., LTD., Yongin-si (KR)

(72) Inventors: Han Su KIM, Yongin-si (KR); Eun A. YANG, Yongin-si (KR)

(21) Appl. No.: 19/532,413

(22) Filed: Feb. 6, 2026

(30) Foreign Application Priority Data
Feb. 7, 2025 (KR) 10-2025-0016121

(51) Int. Cl. H10K 59/122; H10K 59/38; H10K 59/80

(52) U.S. Cl. CPC H10K 59/122; H10K 59/38; H10K 59/877

(57) ABSTRACT

A display device and an electronic device including the display device are provided. The display device includes a light-emitting device, and a color control portion arranged on the light-emitting device. The color control portion includes a bank including color control holes and guide slits independently and respectively connected to the color control holes, and a color control layer in each of the color control holes.

This application claims priority to Korean Patent Application No. 10-2025-0016121, filed on February 7, 2025, and all the benefits accruing therefrom under 35 U.S.C. §119, the content of which in its entirety is herein incorporated by reference.

### BACKGROUND

### 1. Field

Embodiments of the present disclosure relate to a display device and an electronic device including the display device. More particularly, embodiments of the present disclosure relate to a display device including a light-emitting device and a color control portion, and an electronic device including the display device.

### 2. Descriptions of the Related Art

In a display device such as an organic light emitting diode (OLED) display device and a liquid crystal display (LCD) device, a display substrate including thin film transistors (TFTs) and various wirings may be provided, and a display structure including electrodes and emission layers may be formed on the display substrate.

For example, the OLED display device may include a light-emitting device including an organic emission layer. In some cases, a color filter may be added to improve image or color properties generated from the light-emitting device.

### SUMMARY

According to an aspect of the present disclosure, there is provided a display device having improved optical property and image reliability.

According to an aspect of the present disclosure, there is provided a method of manufacturing a display device having improved optical property and image reliability.

According to an aspect of the present disclosure, there is provided an electronic device including a display device with improved optical property and image reliability.

A display device may include a light-emitting device, and a color control portion arranged on the light-emitting device. The color control portion may include a bank including color control holes and guide slits independently and respectively connected to the color control holes, and a color control layer in each of the color control holes.

In some embodiments, a plurality of the guide slits may be connected to each of the color control holes.

In some embodiments, guide slits included among the plurality of the guide slits and connected to a color control hole included among the color control holes may be spaced apart from each other along a hole perimeter of the color control hole.

In some embodiments, the plurality of the guide slits may extend in different respective directions.

In some embodiments, each of the plurality of the guide slits connected to a color control hole included among the color control holes may extend in a radial direction from a center of the color control hole.

In some embodiments, the plurality of the guide slits may include guide slits having different respective lengths.

In some embodiments, for each of the guide slits, a width of an upper portion of the guide slit may be smaller than a width of a lower portion of the guide slit.

In some embodiments, each of the guide slits may have a trapezoidal cross-section.

In some embodiments, for each of the guide slits, an inner angle between a bottom surface of the guide slit and a side wall of the guide slit may be range from 50° to 85°.

In some embodiments, for a guide slit connected to a color control hole comprised among the color control holes, an end portion of the guide slit may be integrally merged with the color control hole, and another end portion of the guide slit may be blocked by the bank.

In some embodiments, a width of the other end portion may be smaller than a width of the end portion.

In some embodiments, the color control holes may include a first color control hole and a second color control hole adjacent to each other. The guide slits may include a first guide slit connected to the first color control hole, and a second guide slit connected to the second color control hole and physically separate from the first guide slit.

In some embodiments, a distance between a center of the first color control hole and a center of the second color control hole may be greater than a sum of a radius of the first color control hole, a length of the first guide slit, a length of the second guide slit, and a radius of the second color control hole.

In some embodiments, the color control holes may include a first color control hole, a second color control hole, and a third color control hole. The color control layer may include a first color control layer including a red colorant layer, a second color control layer including a green colorant layer, and a third color control layer including a blue colorant layer. The first color control layer, the second color control layer, and the third color control layer may fill the first color control hole, the second color control hole, and the third color control hole, respectively.

In some embodiments, the color control portion may further include a base layer on which the bank and the color control layer are arranged, and a light-scattering layer between the color control layer and the base layer. The light-scattering layer may selectively overlap the first color control layer and the second color control layer among the first color control layer, the second color control layer, and the third color control layer.

A display device may include a light-emitting device, and a color control portion arranged on a light-emitting device. The color control portion may include a bank including a color control hole, and guide slits that are respectively connected to the color control holes and extend in different directions, and a color control layer formed in each of the color control holes.

In some embodiments, the guide slits may be arranged radially along a hole perimeter of the color control hole.

In some embodiments, for each of the guide slits, a width of an upper portion of each of the guide slits may be smaller than a width of the lower portion of each of the guide slits.

An electronic device may include a display device, a memory, and a processor executing data included in the memory to control an operation of the display device. The display device may include a light-emitting device, and a color control portion arranged on the light-emitting device. The color control portion may include a bank including color control holes and guide slits independently and respectively connected to the color control holes, and a color control layer in each of the color control holes.

In some embodiments, the electronic device may include virtual reality glasses, augmented reality glasses, a smartphone, a tablet PC, a laptop, a TV, a desk monitor, smart glasses, a head-mounted display, a smart watch, or a vehicle display.

According to embodiments of the present disclosure, guide slits connected to a color control hole may be formed in a bank in which the color control hole is formed. Colorant droplets dropped on a top surface of the bank may be guided into the color control hole through the guide slits.

Thus, desired optical/color properties of a color control portion may be effectively implemented while preventing color mixing between color control layers of different colors, and non-filling of the color control hole.

### BRIEF DESCRIPTION OF THE DRAWINGS

FIG. 1 is a schematic plan view of a display device according to embodiments.

FIG. 2 is a schematic plan view illustrating a color control portion in a display device according to embodiments.

FIG. 3 is a schematic cross-sectional view of a display device according to embodiments.

FIG. 4 is a schematic cross-sectional view illustrating a light-emitting device of a display device according to some embodiments.

FIG. 5 is a schematic plan view illustrating a color control hole and a top surface of a bank according to embodiments.

FIG. 6 is a schematic cross-sectional view illustrating a guide slit according to embodiments.

FIG. 7 is a schematic plan view illustrating a color control hole and a top surface of a bank according to embodiments.

FIG. 8 is a schematic cross-sectional view illustrating formation of a color control layer according to embodiments.

FIG. 9 is a schematic plan view illustrating a color control hole and a top surface of a bank according to embodiments.

FIG. 10 is a schematic plan view illustrating a color control hole and a top surface of a bank according to embodiments.

FIG. 11 is an exploded perspective view illustrating an electronic device according to embodiments.

FIG. 12 is a block diagram of an electronic device according to an embodiment.

FIG. 13 is a schematic diagram of electronic devices according to embodiments.

### DETAILED DESCRIPTION

Hereinafter, embodiments of the present invention will be described in more detail with reference to the attached drawings. The same reference numerals can l be used for indicating the same elements in the drawings, and repeated descriptions of the same elements can be omitted. Embodiments disclosed in the attached drawings are examples, and is to be understood to include all modifications, equivalents and substitutes included in the spirit and technical scope of the present invention.

The terms "on", "connected", "coupled," and the like, used herein refers to a direct placement/connection/combination, and also refers to a case where another element is interposed two different elements.

The terms such as "first", "second", "below", "lower", "upper", "above," and the like, are used in a relative sense to distinguish different elements or positions, and do not specify an absolute position or an absolute order.

The term “adjacent” used herein may refer to cases in which elements are relatively close to but spaced apart from one another. In some aspects, elements described as adjacent to one another may be neighboring one another but spaced apart by a predetermined distance. For example, two elements (e.g., a color control hole and another color control hole, a color control layer and another color control layer) described as adjacent to one another may be neighboring one another without other elements being located between the two elements

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ± 30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel. The term “substantially symmetrical” means approximately or actually symmetrical.

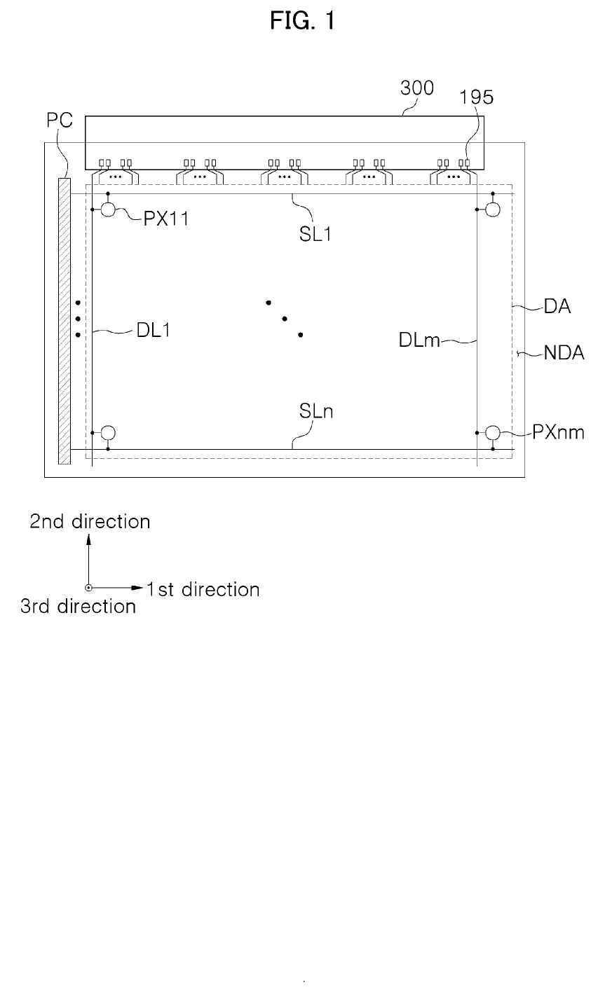

FIG. 1 is a schematic plan view of a display device according to embodiments. For example, FIG. 1 is a plan view illustrating an arrangement of pixels of a display device according to embodiments.

In FIG. 1, a first direction and a second direction may refer to two directions parallel to a display surface of a display device and perpendicular to each other. For example, the first direction may correspond to an X-direction (a row direction), and the second direction may correspond to a Y-direction (a column direction) of the display device. A third direction may be perpendicular to the first direction and the second direction. The third direction may correspond to a Z-direction (a thickness direction) of the display device.

The definitions of the directions described herein may be equally applied to the accompanying drawings.

Referring to FIG. 1, a plurality of pixels PX11 to PXnm may be arranged in a display area DA of the display device.

According to embodiments, a pixel circuit including scan lines (or gate lines SL1 to SLn) forming first to nth rows and data lines DL1 to DLm forming first to mth columns may be arranged on a base substrate 100 of the display device. Each of the pixels PX11 to PXnm may be connected to a scan line of a corresponding row among a plurality of scan lines SL1 to SLn and a data line of a corresponding column among a plurality of data lines DL1 to DLm.

Each of the pixels PX11 to PXnm may further include a pixel driving circuit including a transistor and a light-emitting device as described herein. Although not illustrated in detail in FIG. 1, the pixel circuit may further include wirings such as a power line, a ground line, or the like.

In FIG. 1, data lines DL1 to DLm extend in the second direction, and scan lines SL1 to SLn extend in the first direction, but the present inventive concepts are not limited to the construction illustrated in FIG. 1.

A peripheral circuit PC may be disposed in the non-display area NDA corresponding to a peripheral area with respect to the display area DA. For example, the peripheral circuit PC may include a gate driving circuit. The gate driving circuit may be integrated into the display device by an oxide semiconductor gate (OSG) driver circuit process, an amorphous silicon gate (ASG) driver circuit process, or a polysilicon gate (PSG) driver circuit process.

The peripheral circuit PC may further include a data driver, a gate driver, a light-emitting driver, a power voltage generator, a timing controller, or the like.

The display device may further include a printed circuit board 300. Pads 195 of the pixel circuit may be assembled on one side of the non-display area NDA. A printed circuit board 300 may be electrically connected to the pixel circuit through the pads 195. For example, the printed circuit board 300 may be electrically connected to the pads 195 by a heating-compression process using a conductive intermediate structure such as an anisotropic conductive film (ACF).

An integrated circuit (IC) such as a data driving circuit may be disposed on the printed circuit board 300. In some embodiments, an integrated circuit IC chip in the form of a chip-on-film (COF) may be mounted on the printed circuit board 300.

Hereinafter, elements/structures of the display device of the present disclosure may be described using an example of an organic light-emitting display device. However, the display device disclosed herein may be applied to various types of display devices such as an inorganic light-emitting display device and a quantum dot light-emitting display device, or the like.

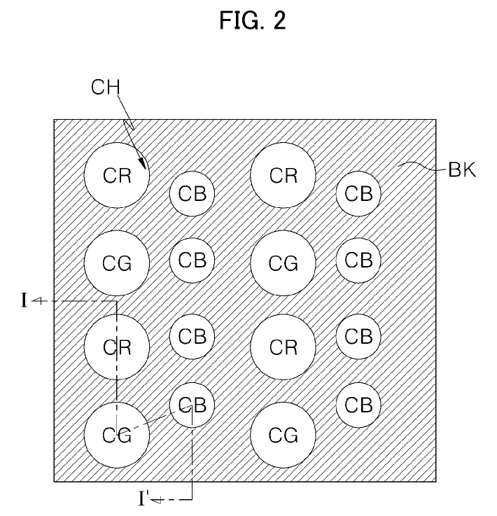

FIG. 2 is a schematic plan view illustrating a color control portion of a display device according to embodiments.

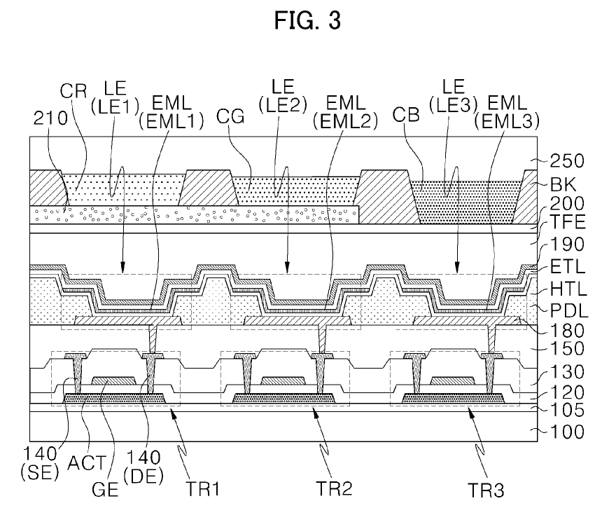

Referring to FIG. 2, e.g., a color control portion may be disposed on an encapsulation layer TFE (see FIG. 3) of the display device. The color control portion may include a color control layer and a bank BK that may distinguish/define the color control layer.

For example, the bank BK may include a polymer resin material or a photoresist material having light-shielding properties, and may be formed by a photo-lithography process including exposure and development processes.

The bank BK may include color control holes CH formed by the photo-lithography process. The color control layer may be disposed in each of the color control holes CH.

The color control layer may include a first color control layer CR, a second color control layer CG, and a third color control layer CB. According to embodiments, the color control layer may serve as a colored layer of a color filter.

The color control layer may be formed using a colored resin composition including a binder resin and a colorant (e.g., a dye and/or a pigment). According to embodiments, the color control layer may be formed by filling the colored resin composition into the color control hole CH by a printing process such as an inkjet process.

In some embodiments, the first color control layer CR, the second color control layer CG, and the third color control layer CB may be formed as a red color layer, a green color layer, and a blue color layer, respectively.

For example, as illustrated in FIG. 2, the first color control layer CR and the second color control layer CG may be alternately and repeatedly arranged in the second direction. The third color control layer CB may have an area smaller than an area of each of the first color control layer CR or the second color control layer CG. The third color control layer CB may be adjacent to the first color control layer CR or the second color control layer CG in the second direction.

For example, the first color control layer CR and the second color control layer CG may be alternately and repeatedly arranged to form a color control column. The color control column may be repeatedly arranged in the first direction. The third color control layers CB may be repeatedly arranged in the second direction between the adjacent color control columns.

In an embodiment, a color control group may be defined by one first color control layer CR and one second color control layer CG neighboring in the second direction, and two third color control layers CB adjacent to the one first color control layer CR and the one second color control layer CG. The color control group may be repeatedly arranged in the first direction and the second direction.

The arrangement of the color control layers described with reference to FIG. 2 is provided as an example, and the structure of the color control portion included in the display device of the embodiments of the present disclosures is not limited to that illustrated in FIG. 2.

FIG. 3 is a schematic cross-sectional view of a display device according to embodiments. For example, FIG. 3 is a cross-sectional view taken along a line I-I′ of FIG. 2 in a thickness direction (the third direction).

Referring to FIG. 3, the display device may include a base substrate 100, a pixel circuit, and a light-emitting device LE.

The base substrate 100 may serve as a back-plane substrate of a display device. A glass substrate or a plastic substrate may be used as the base substrate 100. In some embodiments, the base substrate 100 may include a polymer material having transparency and flexibility. In this case, the base substrate 100 may be used in a transparent flexible display device.

For example, the base substrate 100 may include a polymer material such as polyimide, polysiloxane, an epoxy resin, an acrylic resin, polyester, or the like. In an embodiment, the base substrate 100 may include polyimide.

A buffer layer 105 may be formed on a top surface of the base substrate 100. Moisture penetrating through the base substrate 100 may be blocked by the buffer layer 105, and diffusion of impurities between the base substrate 100 and structures formed on the base substrate 100 may also be blocked by the buffer layer 105. The buffer layer 105 may be entirely formed over the display area DA and the non-display area NDA of the base substrate 100, and may entirely cover the top surface of the base substrate 100.

The buffer layer 105 may include, e.g., an inorganic insulating material such as silicon oxide, silicon nitride, or silicon oxynitride. These may be used alone or in a combination thereof.

In some embodiments, the buffer layer 105 may have a stacked structure including a silicon oxide layer and a silicon nitride layer. The buffer layer 105 may be formed by a deposition process such as a chemical vapor deposition (CVD) process, a sputtering process, an atomic layer deposition (ALD) process, or the like, to include the inorganic insulating material described herein.

In some embodiments, the buffer layer 105 may include an organic layer, and may have a multi-layered structure of an organic layer and an inorganic layer.

The pixel circuit may include wirings including the scan lines and the data lines described with reference to FIG. 1, and transistors TR1, TR2 and TR3 that may electrically interact with the wirings. The transistors TR1, TR2 and TR3 may be electrically connected to light-emitting devices LE1, LE2 and LE3.

The transistors TR1, TR2 and TR3 may include an active layer ACT, a gate insulation layer 120 and a gate electrode GE.

The active layer ACT may be disposed on the buffer layer 105, and may be patterned by a photo-lithography process to be repeatedly/regularly arranged at each pixel. The active layer ACT may include a silicon compound such as polysilicon or amorphous silicon. A p-type dopant or an n-type dopant may be doped in a partial region of the active layer ACT, such that the active layer ACT may include a source region, a drain region, and a channel region.

The active layer ACT may include an oxide semiconductor such as indium gallium zinc oxide (IGZO), zinc tin oxide (ZTO), or indium tin zinc oxide (ITZO).

The gate insulation layer 120 may be formed on the active layer 110, and the gate electrode GE may be stacked on the gate insulation layer 120. As illustrated in FIG. 3, the gate insulation layer 120 may be provided continuously and commonly in a plurality of transistors TR1, TR2 and TR3 or pixels of different colors. Alternatively, the gate insulation layer 120 may be formed in a pattern shape partially covering each active layer 110.

The gate electrode GE may overlap the channel region of the active layer ACT in the third direction. A scan signal may be transmitted from the scan line through the gate electrode GE.

The gate insulation layer 120 may be formed by the above-mentioned deposition process to include an inorganic insulating material such as silicon oxide, silicon nitride, silicon oxynitride, or the like.

In some embodiments, the source region and the drain region may be formed in the active layer ACT by using the gate electrode GE as an ion implantation mask.

An insulating interlayer 130 covering the gate electrode GE and the gate insulation layer 120 may be formed on the active layer ACT. A connection electrode 140 being in contact with or electrically connected to the active layer ACT may be formed on the insulating interlayer 130.

The insulating interlayer 130 may be formed by the above-mentioned deposition process to include an inorganic insulating material such as silicon oxide, silicon nitride, silicon oxynitride, or the like. The insulating interlayer 130 may be formed in a single-layered structure or a multi-layered structure including different materials.

In some embodiments, when the gate insulation layer 120 has the individual pattern shape and the active layer ACT includes the oxide semiconductor, hydrogen (H) included in the insulating interlayer 130 may be diffused or transferred to the active layer ACT when forming the insulating interlayer 130. Accordingly, a carrier concentration may be increased by hydrogen, and thus the source region and the drain region may be formed at side portions of the active layer ACT.

The connection electrode 140 may penetrate the insulating interlayer 130, and may be connected to the active layer ACT. The connection electrode 140 may also penetrate the gate insulation layer 120.

The connection electrode 140 may include a source electrode SE connected to or in contact with the source region of the active layer ACT, and a drain electrode DE connected to or in contact with the drain region of the active layer ACT.

Contact holes may be formed by partially etching the insulating interlayer 130. For example, the contact holes exposing the source region and the drain region, respectively, may be formed. A metal layer filling the contact holes may be formed on the insulating interlayer 130, and the metal layer may be partially etched to form the source electrode SE and the drain electrode DE. For example, a data signal may be transferred from the data line through the source electrode SE.

The gate electrode GE and the connection electrode 140 may include a metal such as Ag, Mg, Al, W, Cu, Ni, Cr, Mo, Ti, Pt, Ta, Nd, Sc, or the like, an alloy thereof, or a nitride thereof. The gate electrode GE and the connection electrode 140 may be formed by the above-mentioned deposition process such as a sputtering process. The gate electrode GE and/or the connection electrode 140 may have a multi-layered structure including different metal layers.

A planarization layer 150 covering the connection electrodes 140 may be formed on the insulating interlayer 130. The planarization layer 150 may accommodate a via portion electrically connecting the pixel electrode 180 to the drain electrode 160.

In some embodiments, the planarization layer 150 may include an organic material such as polyimide, an epoxy resin, an acrylic resin, polyester, a siloxane resin, benzocyclobutene (BCB), or the like. The planarization layer 150 may be formed by a coating process such as a spin coating process or the above-mentioned deposition process described herein.

The pixel electrode 180 may be formed in each pixel to be electrically connected to the transistor. The pixel electrode 180 may be formed on the planarization layer 150 to be electrically connected to the drain electrode DE.

For example, the planarization layer 150 may be partially etched to form a via hole exposing a top surface of the drain electrode DE. A conductive layer filling the via hole and including a metal or a transparent conductive oxide may be formed on a top surface of the planarization layer 150. The conductive layer may be etched to form the pixel electrode 180. The pixel electrode 180 may include the via portion filling the via hole.

The pixel electrode 180 may serve as an anode, and may include a high work function conductive material capable of promoting hole injection. The pixel electrode 180 may be formed as a transmissive electrode. The pixel electrode 180 may include a transparent conductive oxide such as indium tin oxide (ITO), indium zinc oxide (IZO), zinc oxide (ZnO), indium tin zinc oxide (ITZO), or the like.

The pixel electrode 180 may be formed as a translucent electrode or a reflective electrode. The pixel electrode 180 may include a metal selected from Ag, Mg, Cu, Al, Pt, Pd, Au, Ni, Nd, Ir, Cr, Li, Ca, Mo, Ti, W, In, Sn, and Zn, or an alloy or a compound (e.g., LiF) including at least one therefrom.

The pixel electrode 180 may have a single-layered structure or a multi-layered structure. For example, the pixel electrode 180 may have a triple-layered structure of ITO/Ag/ITO or ITO/Al/ITO.

A pixel defining layer PDL exposing a top surface of the pixel electrode 180 may be formed on the planarization layer 150. The pixel defining layer PDL may be formed to at least partially expose the top surface of the pixel electrode 180 such that a pixel may be defined. The pixel defining layer PDL may cover a peripheral portion of the pixel electrode 180.

For example, a pixel region or a light-emitting region may be defined by a sidewall of the pixel defining layer PDL. A first pixel including the first transistor TR1 and the first light-emitting device LE1, a second pixel including the second transistor TR2 and the second light-emitting device LE2, and a third pixel including the third transistor TR3 and the third light-emitting device LE3 may be separated from each other and defined by the pixel defining layer PDL.

In some embodiments, the first pixel, the second pixel and the third pixel may correspond to a red pixel, a green pixel, and a blue pixel, respectively.

The pixel defining layer PDL may include, e.g., an organic material such as a polysiloxane resin, a polyimide resin, an acrylic resin, or the like. The pixel defining layer PDL may include a colorant material such as a black pigment/dye dispersed in the resin material. The pixel defining layer PDL may include an inorganic layer such as a silicon oxide layer and/or a silicon nitride layer

In some embodiments, the pixel defining layer PDL may have a stepped structure as illustrated in FIG. 3.

An emission layer EML may be disposed on the exposed surface of the pixel electrode 180. In some embodiments, the emission layer EML may include an organic light-emitting material independently patterned for each red pixel, a green pixel and a blue pixel to generate different colored lights for each pixel.

The emission layer EML may include a first emission layer EML1 that may be included in the first pixel and may include a red organic light-emitting material, a second emission layer EML2 that may be included in the second pixel and may include a green organic light-emitting material, and a third emission layer EML3 that may be included in the third pixel and may include a blue organic light-emitting material.

For example, the organic light-emitting material may include a host material excited by holes and electrons, and a dopant material increasing luminous efficiency through absorption and release of energy.

In some embodiments, a hole transport layer HTL may be disposed between the pixel electrode 180 and the emission layer EML. An electron transport layer ETL may be disposed on the emission layer EML.

The hole transport layer HTL and the electron transport layer ETL may extend continuously and commonly throughout a plurality of the light-emitting devices LE and the pixels.

For example, the hole transport layer HTL may include a hole transporting material such as m-MTDATA (4,4',4"-[tris(3-methylphenyl)phenylamino] triphenylamine), TDATA (4,4'4"-tris(N,N-diphenylamino)triphenylamine), 2-TNATA (4,4',4"-tris[N(2-naphthyl)-N-phenylamino]-triphenylamine), NPB (N,N'-di(naphthalene-l-yl)-N,N'-diphenyl-benzidine), TPD (N,N'-bis(3-methylphenyl)-N,N'-diphenyl-[1,1'-biphenyl]-4,4'-diamine), TCTA (4,4',4"-tris(N-carbazolyl)triphenylamine), PEDOT/PSS (poly(3,4-ethylenedioxythiophene)/poly(4-styrenesulfonate)), or the like.

For example, the electron transport layer ETL may include an electron transporting material such as an anthracene-based compound, Alq3 (tris(8-hydroxyquinolinato)aluminum), TPBi (1,3,5-Tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1'-biphenyl-4-olato)aluminum), or the like.

The emission layer EML, the hole transport layer HTL, and/or the electron transport layer ETL may be formed by a process such as a thermal deposition, a vapor deposition, a vacuum deposition, a spin coating, an inkjet printing, a laser printing, a casting, a laser thermal transfer, or the like. For example, a selective deposition of the emission layer EML for each pixel may be effectively performed by the pixel defining layer PDL having the stepped structure.

In some embodiments, a hole injection layer may be further formed between the pixel electrode 180 and the hole transport layer HTL. An electron injection layer may be further formed between a counter electrode 190 and the electron transport layer ETL.

The counter electrode 190 may be disposed on the pixel defining layer PDL and the emission layer EML. The counter electrode 190 may be formed on the electron transport layer ETL.

The counter electrode 190 may be a common electrode continuously and commonly included in a plurality of the light-emitting regions or the pixels.

The counter electrode 190 may serve as an electron injection electrode or a cathode. The counter electrode 190 may include a metal, an alloy, an electrically conductive compound, or the like, having a low work function.

For example, the counter electrode 190 may include lithium (Li), silver (Ag), magnesium (Mg), aluminum (Al), aluminum-lithium (Al-Li), calcium (Ca), magnesium-indium (Mg-In), magnesium-silver (Mg-Ag), ytterbium (Yb), silver-ytterbium (Ag-Yb), ITO, IZO, or the like. These may be used alone or in a combination of two or more therefrom.

The counter electrode 190 may be formed as a transmissive electrode, a translucent electrode, or a reflective electrode. The counter electrode 190 may have a single-layered structure or a multi-layered structure.

The light-emitting device LE may be defined by the stacked structure of the pixel electrode 180, the hole transport layer HTL, the emission layer EML, the electron transport layer ETL, and the counter electrode 190. For example, the light-emitting device LE may be electrically connected to the transistor of each pixel through the drain electrode DE.

The light-emitting devices LE may include the first light-emitting device LE1, the second light-emitting device LE2, and the third light-emitting device LE3 including the first emission layer EML1, the second emission layer EML2 and the third emission layer EML3, respectively. In some embodiments, the first light-emitting device LE1, the second light-emitting device LE2, and the third light-emitting device LE3 may be provided as a red light-emitting device, a green light-emitting device, and a blue light-emitting device, respectively.

An encapsulation layer TFE covering the light-emitting devices LE1, LE2 and LE3 may be disposed on the counter electrode 190. The encapsulation layer TFE may be disposed on the pixel defining layer PDL and the light-emitting devices LE1, LE2 and LE3 to protect the light-emitting devices LE1, LE2 and LE3 from moisture or oxygen.

The encapsulation layer TFE may include an inorganic layer including silicon nitride (SiNx), silicon oxide (SiOx), indium tin oxide, indium zinc oxide, or any combination thereof; an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, or the like), an epoxy resin (e.g., aliphatic glycidyl ether (AGE)), or any combination thereof; or a combination of the inorganic and organic layers.

The encapsulation layer TFE may be formed in a single-layered structure or a multi-layered structure. In some embodiments, the encapsulation layer TFE may have a sequential stacked structure of a first inorganic layer, an organic layer and a second inorganic layer.

The color control portion may be disposed on the encapsulation layer TFE. The color control portion may include the base layer 200, the bank BK formed on the base layer 200, and the color control layers CR, CG and CB defined by the bank BK.

The base layer 200 may serve as a substrate for the bank BK and the color control layers CR, CG and CB, and the base layer 200 may include the above-mentioned inorganic insulating material.

As described with reference to FIG. 2, the first color control layer CR, the second color control layer CG and the third color control layer CB may include a red colored layer, a green colored layer and a blue colored layer, respectively. The first color control layer CR, the second color control layer CG and the third color control layer CB may overlap the first light-emitting device LE1, the second light-emitting device LE2 and the third light-emitting device LE3, respectively, in the third direction.

The color control portion may further include a light-scattering layer 210 disposed between the color control layer and the base layer 200. The light-scattering layer 210 may include a binder resin layer and light scattering particles such as TiO2, ZnO, Al2O3, SiO2, hollow silica, or the like, dispersed in the binder resin layer.

In some embodiments, the light-scattering layer 210 may be selectively disposed under the first color control layer CR and the second color control layer CB, and may not be disposed under the third color control layer CB. Accordingly, luminous efficiency may be relatively increased in the blue light-emitting region, and optical reliability may be improved by preventing reflection of external light in the red and green light-emitting regions.

The color control portion may further include a protective layer 250 covering the bank BK and the color control layers CR, CG and CB. The protective layer 250 may include the inorganic insulating material and/or the organic insulating material described herein.

According to embodiments, the color control portion may serve as a color filter structure. The first color control layer CR, the second color control layer CG and the third color control layer CB may serve as a red color filter, a green color filter and a blue color filter, respectively.

According to embodiments, the color control portion may be formed as an on-cell film (OCF), and the display device may have a pol-less structure that does not include a polarizing plate.

The color control portion may be disposed such that the first color control layer CR, the second color control layer CG and the third color control layer CB may be superimposed over the red light-emitting device, the green light-emitting device and the blue light-emitting device, respectively. Thus, reflection of external light may be sufficiently reduced and color purity of each pixel may be enhanced without using the polarizing plate.

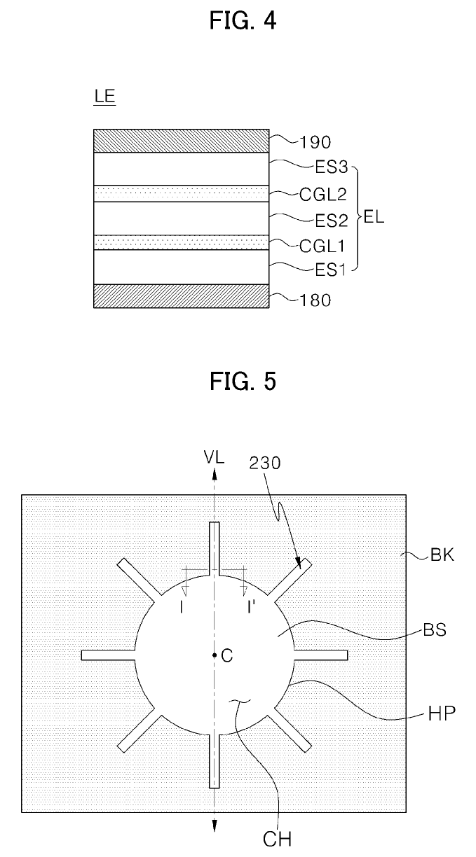

FIG. 4 is a schematic cross-sectional view illustrating a light-emitting device of a display device according to some embodiments.

Referring to FIG. 4, the light-emitting device LE of the display device described with reference to FIG. 3 may have a tandem structure.

As illustrated in FIG. 4, the light-emitting device LE may include a light-emitting portion EL disposed between the first electrode 180 and the second electrode 190, and the light-emitting portion EL may include a plurality of light-emitting structures. Each of the light-emitting structures may include the hole transport layer HTL, the emission layer EML, and the electron transport layer ETL.

In some embodiments, the light emitting structures may include a first light-emitting structure ES1, a second light-emitting structure ES2, and a third light-emitting structure ES3.

Charge generation layers may be disposed between neighboring light-emitting structures. The charge generation layers may include a p-type charge generation layer and/or an n-type charge generation layer. The charge generation layers may include a first charge generation layer CGL1 between the first light-emitting structure ES1 and the second light-emitting structure ES2, and a second charge generation layer CGL2 between the second light-emitting structure ES2 and the third light-emitting structure ES3.

According to embodiments, the first light-emitting structure ES1, the first charge generation layer CGL1, the second light-emitting structure ES2, the second charge generation layer CGL2, the third light-emitting structure ES3, and the counter electrode 190 may be sequentially stacked from the top surface of the pixel electrode 180.

The light-emitting portion EL included in the light-emitting device LE may be provided as a common layer of the first to third light-emitting devices LE1, LE2 and LE3. In some embodiments, blue light or white light may be emitted from the light-emitting portion EL, and color for each pixel may be implemented by the above-described color control portion described herein.

FIG. 4 illustrates a triple-layered tandem structure light-emitting device LE as an example, but the light-emitting device LE may have a tandem structure of two layers, or four or more layers of the light-emitting structures.

FIG. 5 is a schematic plan view illustrating a color control hole and a top surface of a bank according to embodiments.

Referring to FIG. 5, as described herein, the color control portion may include the bank BK in which the color control hole CH is formed. The color control layer may be formed in the color control hole CH as described herein.

The color control hole CH may have a circular shape or an elliptical shape in a plan view. A top surface of the bank BK may include a hole perimeter HP of the color control hole CH. The hole perimeter HP may be defined as a boundary between a sidewall of the bank BK in the color control hole CH and the top surface of the bank BK.

According to embodiments, a plurality of guide slits 230 may be formed along the hole perimeter HP of the color control hole CH. In a plan view of FIG. 5, the guide slits 230 may penetrate or extend into the bank BK from the hole perimeter HP.

One end portion of the guide slit 230 may be merged with the color control hole CH. Accordingly, the guide slit 230 and the color control hole CH may communicate with each other. For example, the guide slit 230 may be fluid-connected to the color control hole CH through the one end portion.

The other end portion of the guide slit 230 may be blocked by or end at a sidewall of the bank BK. According to embodiments, each guide slit 230 may be connected to one color control hole CH and may be separated from other adjacent color control holes CH.

According to embodiments, the guide slits 230 may be radially arranged along the hole perimeter HP. In some embodiments, each of the guide slits 230 may extend in a radial direction from a center C of the color control hole CH.

In some embodiments, a pair of the guide slits 230 may be symmetrically arranged with respect to the center C of the color control hole CH. For example, the pair of the guide slits 230 may be positioned together on a virtual straight line passing through the center C of the color control hole CH.

In some embodiments, as illustrated in FIG. 5, the guide slits 230 may be substantially symmetrical to the virtual straight line VL passing through the center C of the color control hole CH.

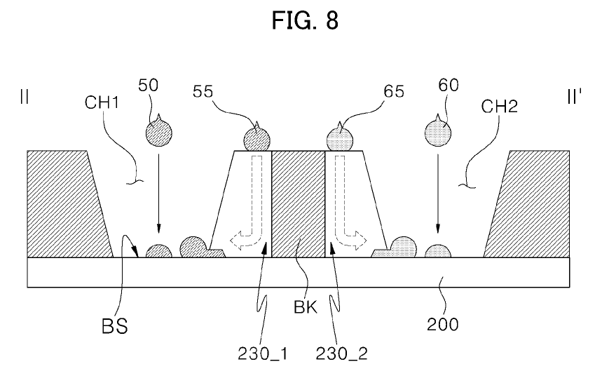

As will be described herein with reference to FIG. 8, colorant droplets dropped on the top surface of the bank BK instead of a bottom surface BS of the color control hole CH may be guided to the bottom surface BS of the color control hole CH through the guide slits 230. Thus, color mixing or color bleeding between adjacent color control holes CH may be prevented, and color purity may be improved.

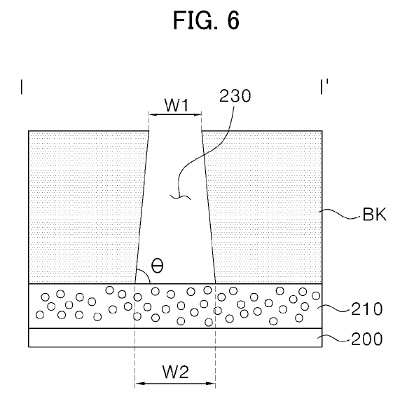

FIG. 6 is a schematic cross-sectional view illustrating a guide slit according to embodiments. For example, FIG. 6 is a cross-sectional view taken along a line I-I′ of FIG. 5 in a thickness direction.

Referring to FIG. 6, a width W2 of a lower portion of the guide slit 230 may be greater than an upper width W1. In an embodiment, a cross-section of the guide slit 230 may have a substantially trapezoidal shape. For example, a width of an inlet of the guide slit 230 may be indicated by W1, a width of a bottom surface of the guide slit 230 may be indicated by W2, and W2 may be greater than W1. The bottom surface of the guide slit 230 may be defined by the top surface of the base layer 200 or the light-scattering layer 210.

In an example in which a colorant droplet dropped on the top surface of the bank BK reaches the inlet of the guide slit 230, the width of the guide slit 230 may be expanded to promote entrance of the color droplet into the guide slit 230.

In some embodiments, an inner angle θ formed by the bottom surface and a sidewall of the guide slit 230 may range from 50o to 85o, from 60o to 85o, or from 70o to 85o. In each of the ranges of the inner angle θ, the guide effect of the colorant droplets through the guide slit 230 into the color control hole CH may be promoted.

In some aspects, light-scattering or reflection of external light generated by colorant droplet residues in the guide slit 230 may be reduced or blocked by the inlet of the guide slit 230 having a narrow width.

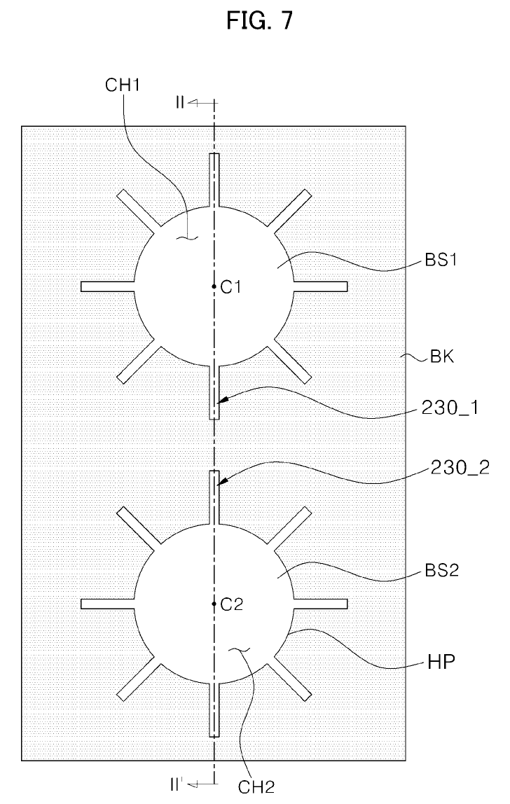

FIG. 7 is a schematic plan view illustrating a top surface of a color control hole and a bank according to embodiments.

Referring to FIG. 7, a first color control hole CH1 and a second color control hole CH2 adjacent to each other may be formed in the bank BK. In some embodiments, color control layers of different colors may be formed in the first color control hole CH1 and the second color control hole CH2. In an embodiment, the first color control layer CR and the second color control layer CG may be formed in the first color control hole CH1 and the second color control hole CH2, respectively (see FIGS. 2 and 3).

As described with reference to FIGS. 5 and 6, first guide slits 230_1 and second guide slits 230_2 may respectively be formed along the hole perimeters HP of the first color control hole CH1 and the second color control hole CH2.

As described herein, the guide slits 230 may be connected to the corresponding color control hole CH, without being connected to other color control holes CH adjacent to the color control hole CH. The first guide slits 230_1 and the second guide slits 230_2 may be physically and spatially separate from each other.

A first bottom surface BS1 of the first color control hole CH1 may have a first center C1. A second bottom surface BS2 of the second color control hole CH2 may have a second center C2.

For example, a distance between the first center C1 and the second center C2 may be greater than a sum of a radius of the first color control hole CH1, a length of any one first guide slit 230_1 of the first guide slits 230_1 (a length in a plan view including the top surface of the bank BK), a length of any one second guide slit 230_2 of the second guide slits 230_2, and a radius of the second color control hole CH2. Accordingly, independent arrangement and separation of the first guide slits 230_1 and the second guide slits b may be stably achieved.

FIG. 8 is a schematic cross-sectional view illustrating formation of a color control layer according to embodiments.

The first color control layer CR and the second color control layer CG may be formed by supplying a first colorant droplet 50 and a second colorant droplet 60 into the first color control hole CH1 and the second color control hole CH2, respectively, through an ink jet process. The droplets 50 and 60 dropped within the hole perimeter HP may fall to the bottom surfaces BS of the color control holes CH1 and CH2 to form the color control layers CR and CG.

As a resolution of a display device increases and critical dimensions of the color control holes CH1 and CH2 decrease, mis-aligned droplets 55 and 65 that may fall to the top surface of the bank BK may be generated.

The first mis-aligned colorant droplet 55 and the second mis-aligned colorant droplet 65 may be induced into the first guide slit 230_1 and the second guide slit 230_2, respectively, as indicated by bent dotted arrows by a capillary force generated by the first guide slit 230_1 and the second guide slit 230_2.

Thereafter, the first mis-aligned colorant droplet 55 and the second mis-aligned colorant droplet 65 may fill each of the first guide slit 230_1 and the second guide slit 230_2, such that the first mis-aligned colorant droplet 55 and the second mis-aligned colorant droplet 65 may enter the first color control hole CH1 and the second color control hole CH2 by a potential energy or a physical pressure.

As described herein, the first guide slit 230_1 and the second guide slit 230_2 may be spatially and physically separate, entrance of the first mis-aligned colorant droplet 55 into the second color control hole CH2 and/or entrance of the second mis-aligned colorant droplet 65 into the first color control hole CH1 may be prevented.

Thus, a high-resolution/fine-dimension color control portion may be obtained with high reliability while preventing non-filling of each color control hole CH1 and CH2, and color mixing between the color control holes CH1 and CH2.

In some embodiments, a width of the guide slit 230 (in a plan view including the top surface of the bank BK) may be about 10 μm or less, from about 1 μm to about 10 μm, from about 2 μm to about 10 μm, from about 2 μm to about 8 μm, or from about 2 μm to about 6 μm. In the above width ranges, a capillary force supportive of guiding the mis-aligned droplets into the guide slit 230 may be generated.

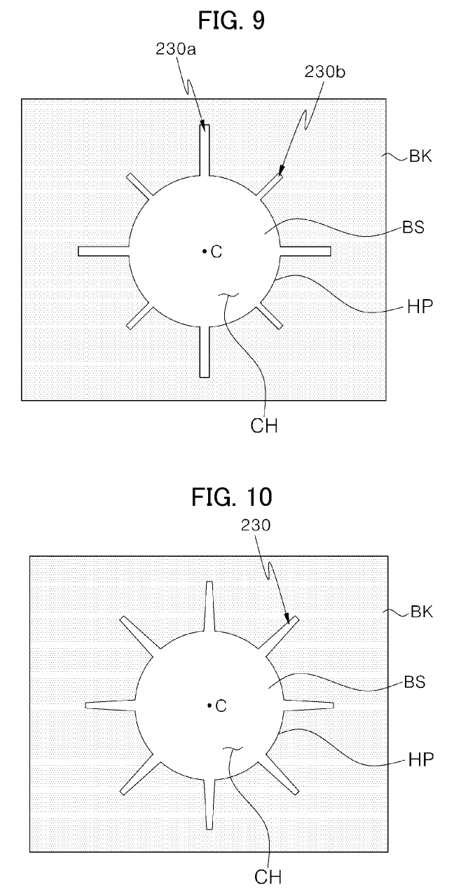

FIG. 9 is a plan view illustrating a color control hole and a top surface of a bank according to embodiments.

Referring to FIG. 9, the guide slit 230 may include guide slits having different lengths. For example, as illustrated in FIG. 9, the guide slits 230 may include a main guide slit 230a having a relatively large length and a sub-guide slit 230b having a relatively small length.

In a non-limiting embodiment, the main guide slit 230a and the sub-guide slit 230b may be arranged alternately and repeatedly along the hole perimeter (HP).

The positions of the main guide slit 230a and the sub-guide slit 230b may be appropriately changed in consideration of the distance between adjacent color control holes, positions of the color control holes, or the like.

FIG. 10 is a plan view illustrating a color control hole and a top surface of a bank according to embodiments.

Referring to FIG. 10, the guide slit 230 may have a variable width. In some embodiments, a width of an end portion of the guide slit 230 blocked by the bank BK may be smaller than a width of an one end portion merged with the color control hole CH. Accordingly, the mis-aligned droplets filled in the guide slit 230 may be easily ejected or guided into the color control hole CH by the potential energy or the pressure.

In an embodiment, a width of the guide slit 230 may gradually increase in a direction from the end portion blocked by the bank BK to the end portion merged with the color control hole CH. For example, the guide slit 230 may have a trapezoidal shape in the plan view.

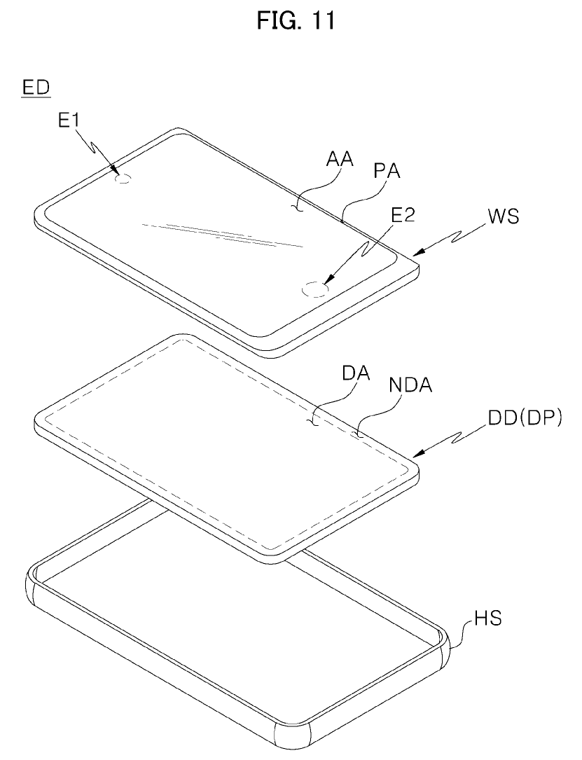

FIG. 11 is an exploded perspective view illustrating an electronic device according to embodiments.

According to example embodiments, the electronic device ED may be implemented in the form of a mobile phone (smart phone), a tablet, a PC, or the like, including the above-described display device.

Referring to FIG. 11, the electronic device may include a window structure WS, a display panel DP, and a housing HS. The display device DD may include a display panel DP including the transistors and the light-emitting devices LE as described herein. The housing HS, the display device DD, and the window structure WS may be sequentially stacked along the third direction.

The window structure WS may provide an external display surface recognized by a user, such as a viewing surface of a mobile phone, and may include a transparent material film. For example, the window structure WS may include glass (e.g., ultra-thin glass (UTG)), a hard coating film, a plastic film, or the like.

An outer surface of the window structure WS may include an active area AA and a peripheral area PA. The active area AA may provide a surface from which an image of the display device DD is substantially displayed and to which a user's touch/command is input. The peripheral area PA may substantially correspond to a bezel area of the display device.

The display device DD or the display panel DP may include a display area DA and a non-display area NDA. The display area DA of the display panel DP may substantially correspond to or overlap the active area AA of the window structure WS. The non-display area NDA of the display panel DP may substantially correspond to or overlap the peripheral area PA of the window structure WS.

In some embodiments, functional device areas E1 and E2 may be included in the active area AA of the window structure WS. For example, a first functional device area E1 may be included at one end portion of the active area AA and may be implemented, e.g., in the form of a camera hole. The second functional device area E2 may serve as a fingerprint sensing area.

For example, a sensor structure for a touch sensing or a fingerprint sensing may be disposed in the display panel DP or between the window structure WS and the display panel DP.

The housing HS may serve as a frame structure or a rear housing of the display device DD or the electronic device ED. A cover panel may be disposed between the housing HS and the display panel DP. The housing HS or the cover panel may include a plate (e.g., an SUS plate) that supports the display panel DP, the printed circuit board 300 (see FIG. 1), or the like. The housing HS or the cover panel may include an elastic body for absorbing shock of the display device DD.

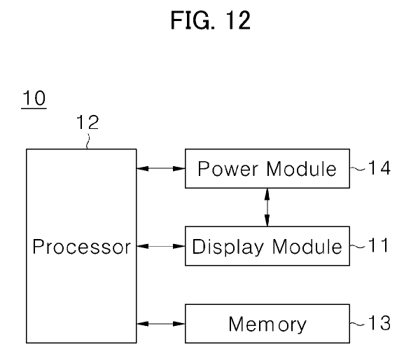

FIG. 12 is a block diagram of an electronic device according to an embodiment.

Referring to FIG. 12, an electronic device 10 according to an embodiment may include a display module 11, a processor 12, a memory 13 and a power module 14.

The processor 12 may include a central processing unit (CPU), an application processor (AP), a graphic processing unit (GPU), a communication processor (CP), an image signal processor (ISP) and/or a controller.

Data information for an operation of the processor 12 or the display module 11 may be stored in the memory 13. In an example in which the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to a generate power for the operation of the electronic device 10.

At least one of components of the electronic device 10 as described herein may be included in the display device according to the above-described embodiments. In some aspects, some of individual modules functionally included in one module may be included in the display device, and others may be provided separately from the display device. For example, the display module 11 may include the display device, and the processor 12, the memory 13 and the power module 14 may be provided in the form of another device in the electronic device 10 different from the display device.

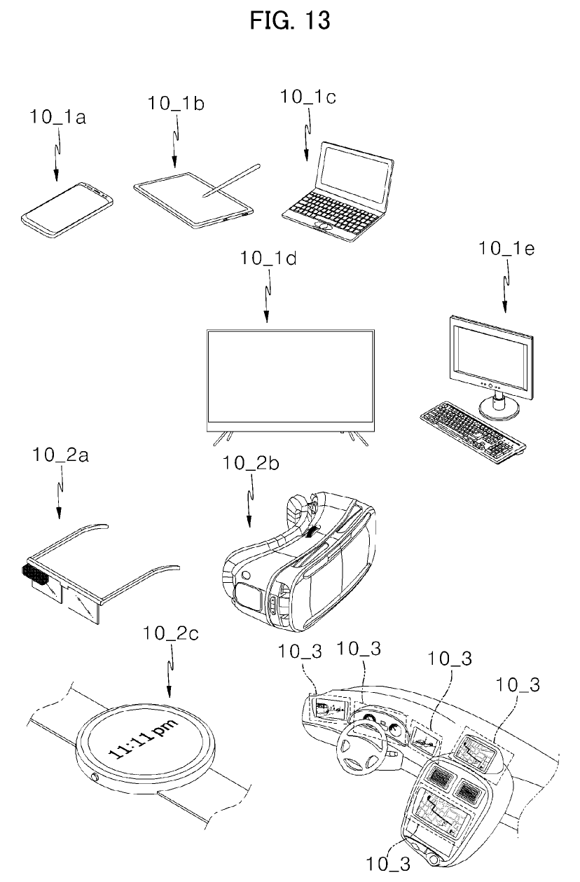

FIG. 13 is a schematic diagram of electronic devices according to embodiments.

Referring to FIG. 13, non-limiting examples of various electronic devices to which the display device according to the above-described embodiments is applied include an electronic device for displaying an image such as a smartphone 10_1a, a tablet PC 10_1b, a laptop 10_1c, a TV 10_1d, a desk monitor 10_1e, or the like; a wearable electronic device including a display module such as smart glasses 10_2a, a head mounted display 10_2b, a smart watch 10_2c, or the like; a vehicle electronic device 10_3 including a display module such as a center information display (CID) disposed at a vehicle instrument panel, a center fascia, a dashboard, or the like, a head-up display, a room mirror display, or the like. The electronic device may include virtual reality glasses or augmented reality glasses.

What is claimed is:

1. A display device, comprising:
a light-emitting device; and
a color control portion arranged on the light-emitting device, the color control portion comprising:
a bank comprising color control holes, and guide slits independently and respectively connected to the color control holes; and
a color control layer in each of the color control holes.

2. The display device of claim 1, wherein a plurality of the guide slits are connected to each of the color control holes.

3. The display device of claim 2, wherein guide slits included among the plurality of the guide slits and connected to a color control hole comprised among the color control holes are spaced apart from each other along a hole perimeter of the color control hole.

4. The display device of claim 2, wherein the plurality of the guide slits extend in different respective directions.

5. The display device of claim 4, wherein each of the plurality of the guide slits connected to a color control hole comprised among the color control holes extends in a radial direction from a center of the color control hole.

6. The display device of claim 2, wherein the plurality of the guide slits comprise guide slits having different respective lengths.

7. The display device of claim 1, wherein for each of the guide slits, a width of an upper portion of the guide slit is smaller than a width of a lower portion of the guide slit.

8. The display device of claim 7, wherein each of the guide slits has a trapezoidal cross-section.

9. The display device of claim 7, wherein for each of the guide slits, an inner angle between a bottom surface of the guide slit and a side wall of the guide slit ranges from 50° to 85°.

10. The display device of claim 1, wherein for a guide slit connected to a color control hole comprised among the color control holes, an end portion of the guide slit is integrally merged with the color control hole, and another end portion of the guide slit is blocked by the bank.

11. The display device of claim 10, wherein a width of the other end portion is smaller than a width of the end portion.

12. The display device of claim 1, wherein:
the color control holes comprise a first color control hole and a second color control hole adjacent to each other, and
the guide slits comprises:
a first guide slit connected to the first color control hole, and
a second guide slit connected to the second color control hole and physically separate from the first guide slit.

13. The display device of claim 12, wherein a distance between a center of the first color control hole and a center of the second color control hole is greater than a sum of a radius of the first color control hole, a length of the first guide slit, a length of the second guide slit, and a radius of the second color control hole.

14. The display device of claim 1, wherein:
the color control holes comprise a first color control hole, a second color control hole, and a third color control hole,
the color control layer comprises a first color control layer comprising a red colorant layer, a second color control layer comprising a green colorant layer, and a third color control layer comprising a blue colorant layer, and
the first color control layer, the second color control layer, and the third color control layer fill the first color control hole, the second color control hole, and the third color control hole, respectively.

15. The display device of claim 14, wherein the color control portion further comprises:
a base layer on which the bank and the color control layer are arranged; and
a light-scattering layer between the color control layer and the base layer, wherein the light-scattering layer selectively overlaps the first color control layer and the second color control layer among the first color control layer, the second color control layer, and the third color control layer.

16. A display device, comprising:
a light-emitting device; and
a color control portion arranged on a light-emitting device, the color control portion comprising:
a bank comprising color control holes and guide slits that are respectively connected to the color control holes and extend in different respective directions; and
a color control layer in each of the color control holes.

17. The display device of claim 16, wherein the guide slits are arranged radially along a hole perimeter of the color control hole.

18. The display device of claim 16, wherein a width of an upper portion of the guide slit is smaller than a width of a lower portion of the guide slit.

19. An electronic device, comprising
a display device;
a memory; and
a processor executing data comprised in the memory to control an operation of the display device, wherein the display device comprises:
a light-emitting device; and
a color control portion disposed on the light-emitting device, the color control portion comprising:
a bank comprising color control holes, and guide slits independently and respectively connected to the color control holes; and
a color control layer in each of the color control holes.

20. The electronic device of claim 19, wherein the electronic device comprises virtual reality glasses, augmented reality glasses, a smartphone, a tablet PC, a laptop, a TV, a desk monitor, smart glasses, a head-mounted display, a smart watch, or a vehicle display.
